(19) United States
(12) Patent Application Publication
(10) Pub. No.: US 2008/0067615 A1
(43) Pub. Date: Mar. 20, 2008

(54) SEMICONDUCTOR DEVICE AND METHOD FOR FABRICATING THEREOF

(76) Inventor: San-Hong Kim, Gyeongi-do (KR)

Correspondence Address: SHERR & NOURSE, PLLC, 620 HERNDON PARKWAY, SUITE 200, HERNDON, VA, 20170, US

(21) Appl. No.: 11/854,358

(22) Filed: Sep. 12, 2007

(30) Foreign Application Priority Data
Sep. 18, 2006 (KR) 10-2006-090065

(51) Int. Cl. H01L 29/94; H01L 21/336

(52) U.S. Cl. 257/408; 438/296; 257/E29.345; 257/E21.409

(57) ABSTRACT

A semiconductor device including at least one of: A well region formed by implanting impurities between isolation layers in a semiconductor substrate. A drift region formed at an upper portion of the well region. A gate pattern formed on the semiconductor substrate while overlapping with one side of the drift region. At least one STI (Shallow Trench Isolation) formed on the drift region, adjacent to the gate pattern.

The present application claims priority under 35 U.S.C. 119 and to Korean Patent Application No. 10-2006-090065 (filed on Sep. 18, 2006), which is hereby incorporated by reference in its entirety.

### BACKGROUND

High voltage devices may employ a Drain Extended NMOS (DENMOS). A DENMOS may be configured to have a breakdown voltage higher than its operational voltage, so that it may be used as a high voltage device. A DENMOS may have a structure of a typical NMOS transistor, but with a drift region in a drain area. A drift region in a DENMOS may have a relatively low density (e.g. 1E16˜5E17 atoms/cm3), which may allow a DENMOS to be used in a high voltage circuit.

Although a DENMOS transistor may have a structure designed to have a relatively high breakdown voltage for operation at high voltages, the efficiency of shunting undesired discharge current upon electrostatic discharge (ESD) may be relatively low. This low efficiency may be due to the drift region having a relatively low density.

An ESD state may occur over a relatively short period of time (e.g. less than approximately 100 nsec). Accordingly, a parasitic NPN-BJT may be incorporated into a DENMOS device, so that a relatively high current (e.g. 1 A to 2 A) can instantaneously flow through the DENMOS. However, current may flow along the surface of a channel of a DENMOS transistor, causing a current localization phenomenon due to EDS stress current.

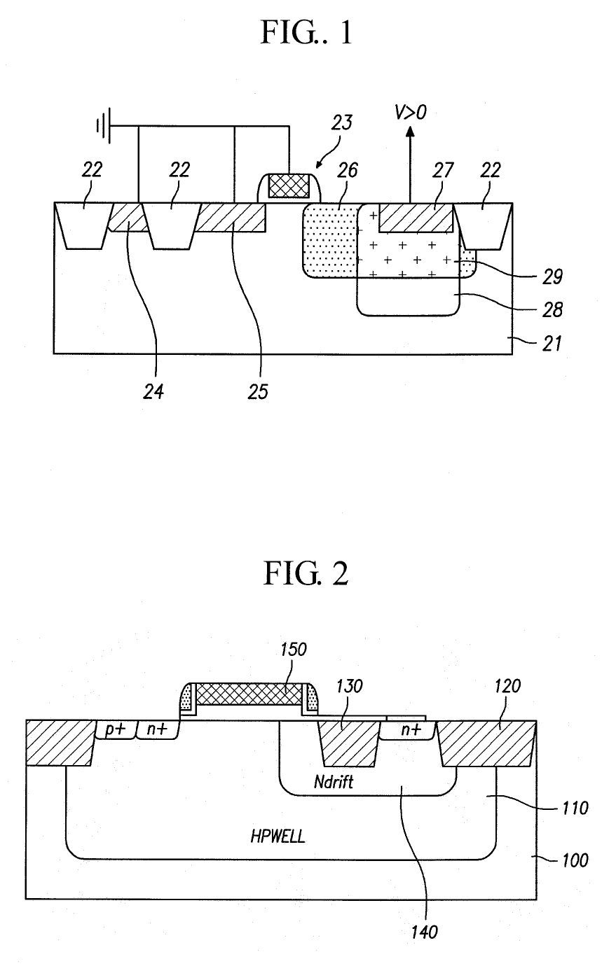

Example FIG. 1 illustrates a TDDNMOS (Triple diffused Drain NMOS), that attempts to mitigate a current localization phenomenon and relatively low efficiency of shunting undesired discharge current. A TDDNMOS may be formed by diffusing impurities in a series of steps.

As illustrated in example FIG. 1, a plurality of isolation layers 22 may be formed in predetermined regions of semiconductor substrate 21. Semiconductor substrate 21 may have a P-well and gate 23 formed between the isolation layers 22. Well pickup region 24 may be formed between isolation layers 22 by implanting P-type dopants into the semiconductor substrate 201. Source active region 25 may be formed between isolation layer 22 and gate 23 by implanting high-density N-type dopant.

N-type dopant implantation processes may be performed in three steps to form a drain between gate 23 and isolation layer 22. A high-density drain active region 27 may be formed in low-density drain drift region 26. Impurity region 28 may be formed in low-density drain drift region 26 such that the impurity region 28 entirely or substantially overlaps high-density drain active region 27.

Source active region 25 may be formed at the same time as drain active region 27, through the same dopant implantation process. After formation of course active region 25 and drain active region 27, their impurity densities may be substantially the same. A P-well under gate 23 may define the channel and may be formed by implanting impurities. The impurity density in a P-well under gate 23 may be less than the impurity density of drain drift region 26.

Gate 23, well pickup region 24, and source active region 25 may be commonly connected to a ground line (Vss line). Drain active region 27 may be connected to a power line or an individual input/output pad.

However, a TDDNMOS (as illustrated in example FIG. 1) may require additional implantation processes to direct current to flow in a vertical direction. Further, in order to improve thermal runaway current, additional implantation and/or mask processes may be necessary. Additional processes may be costly in a manufacturing process, which may be to the detriment of both manufacturers and consumers.

### SUMMARY

Embodiments relate to a semiconductor device having an ESD (electro static discharge) protection function. Embodiments relate to a method of manufacturing a semiconductor device having an ESD (electro static discharge) protection function that limits implantation and/or a mask processes.

In embodiments, a semiconductor device includes at least one of the following: A well region formed by implanting impurities in a semiconductor substrate between isolation layers. A drift region formed at an upper portion of the well region. A gate pattern formed over the semiconductor substrate, which may overlap one side of the drift region. At least one STI (Shallow Trench Isolation) formed on the drift region, adjacent to the gate pattern.

### DRAWINGS

Example FIG. 1 illustrates a TDDNMOS (Triple diffused Drain NMOS).

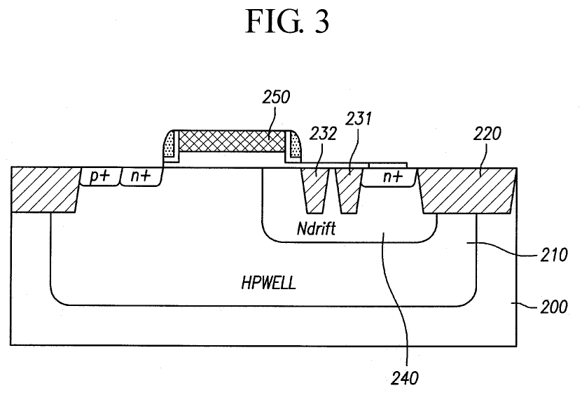

Example FIGS. 2 and 3 illustrate a semiconductor device, in accordance with embodiments.

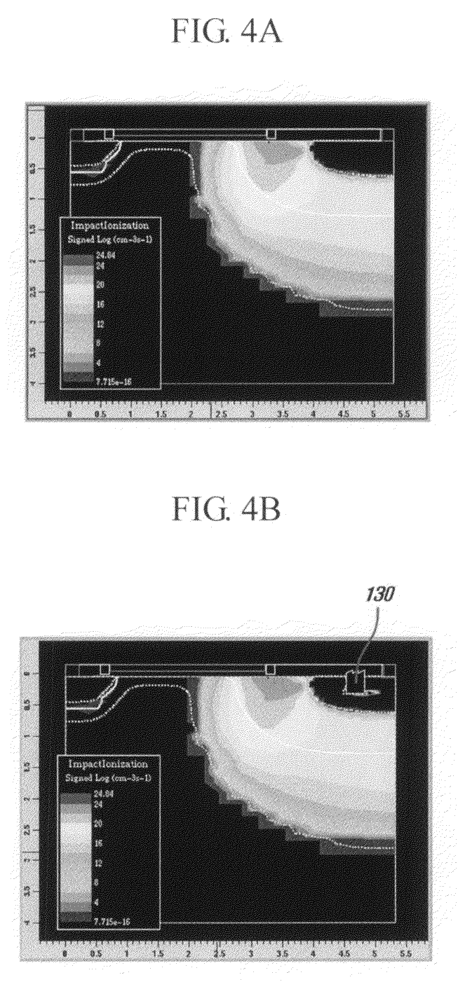

Example FIGS. 4 to 9 illustrate characteristics of a semiconductor device, in accordance with embodiment.

### DESCRIPTION

Example FIG. 2 illustrates aspects of a high voltage ESD protection device, in accordance with embodiments. An oxide layer may be formed on semiconductor substrate 100, in accordance with embodiments. Impurities may be implanted into the semiconductor substrate 100, thereby forming well region 110 (e.g. a HP-well region or an HN-well region). A shallow trench isolation (STI) 130 may be formed in drift region 140 (e.g. a Ndrift region) of semiconductor substrate 100, in accordance with embodiments. An isolation layer 120 may be formed in semiconductor substrate 100. STI 130 may be formed adjacent to gate pattern 150.

In embodiments, an oxide layer may be formed on and/or over semiconductor substrate 100. A photoresist pattern may be formed on and/or over semiconductor substrate 100. An etching process may be performed on semiconductor substrate 100 to form a plurality of trenches. At least one isolation layer 120 and/or STI 130 may be formed in trenches, which may define an active region, in accordance with embodiments. In embodiments, trenches may be filled with silicon oxide (e.g. SiO2) to form at least one isolation layer 120 and/or STI 130.

After forming isolation layers 120 and/or STI 130, P-type or N-type dopants may be implanted into well 110 to form drift region 140, in accordance with embodiments. In embodiments, drift region 140 may be formed substantially outside isolation layers 120. Gate pattern 150 may be formed on and/or over well 110 and isolation layers 120. In embodiments, drift region 140 may have a depth greater than the depth of a source region (which may be formed in a subsequent process). A source region may be asymmetrical to drift region 140.

A capping layer (e.g. including an oxide) may be formed to cover gate pattern 150 including a gate oxide layer, polysilicon, and/or other gate structure. A photoresist pattern may be formed on and/or over the capping layer. Dopants may be implanted into semiconductor substrate 100 using the photoresist pattern as a mask to form a source region and/or a drain region. A source region may be shallowly doped with n+ and p+ dopants. A drain region may be shallowly doped n+ dopant.

A silicon nitride layer may be deposited on and/over the surface of gate pattern 150. A spacer may be formed from the silicon nitride layer on sidewalls of gate pattern 150 (e.g. through an etch back process). A silicide process may be performed relative to the capping layer to impart silicide to a portion of the capping layer.

As illustrated in example FIG. 3, two STIs (STI 231 and STI 232) may be formed in drift region 240, in accordance with embodiments. The two STIs 231 and 232 may be adjacent to a gate pattern 250, in accordance with embodiments. Drift region 240, isolation layer 220, HP-well 210, may be formed in semiconductor substrate 200, in accordance with embodiments.

Example FIGS. 2 and 3 illustrate a high voltage ESD protection device with at least one STI in a drift region between a gate and an drain active region, in accordance with embodiments. In embodiments, the devices illustrated in example FIGS. 2 and 3 may have DENMOS structures, which may maximize ESD protection characteristics.

Example FIG. 4A is a photographic view showing impact ionization of a semiconductor device in a breakdown state, where the device does not have an STI in a drift region. Example FIG. 4B is a photographic view showing impact ionization of a semiconductor device in a breakdown state, where the device has an STI in the drift region, in accordance with embodiments. As illustrated in example FIG. 4B, a depletion region is at and around STI region 130. As illustrated in example FIGS. 4A and 4B, the impact ionization of a semiconductor device shown in FIG. 4B (i.e. with STI in a drift region) is substantially similar to the impact ionization of the semiconductor device shown in FIG. 4A (i.e. device without STI in a drift region).

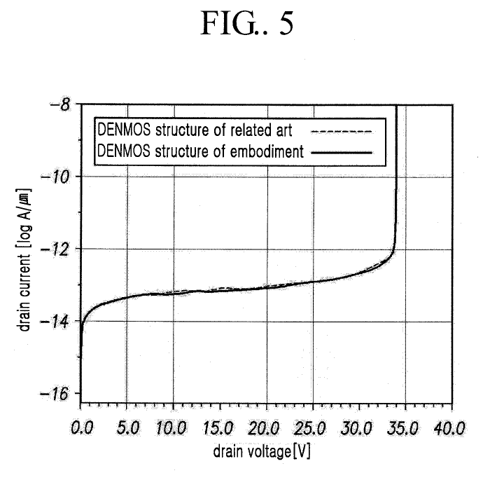

Example FIG. 5 illustrates current-voltage characteristics in ESD protection devices that have an STI in the drift region (“DENMOS structure of embodiment”) and do not have STI in the drift region (“DENMOS structure of related art”). As illustrated, the current-voltage characteristics are substantially the same, regardless of the presence of an STI in a drift region. Accordingly, the current-voltage performance of an ESD protection may not be substantially affected by incorporation of an STI in a drift region during operation at the breakdown voltage, in accordance with embodiments.

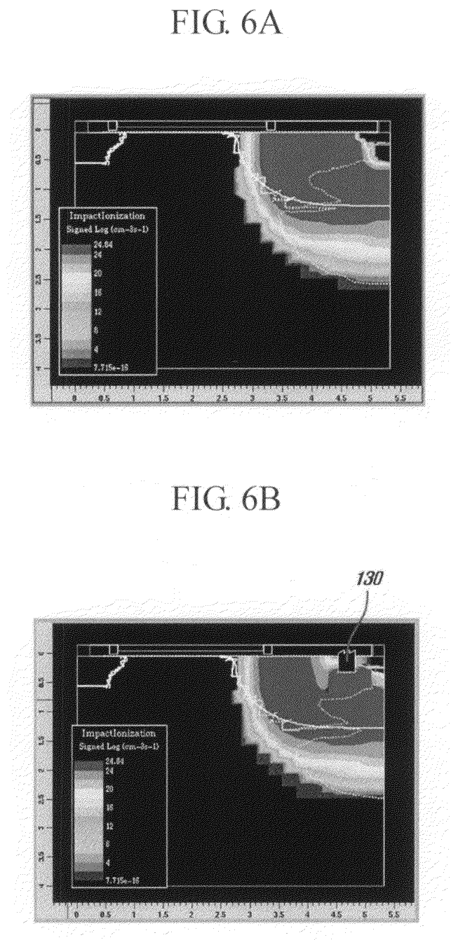

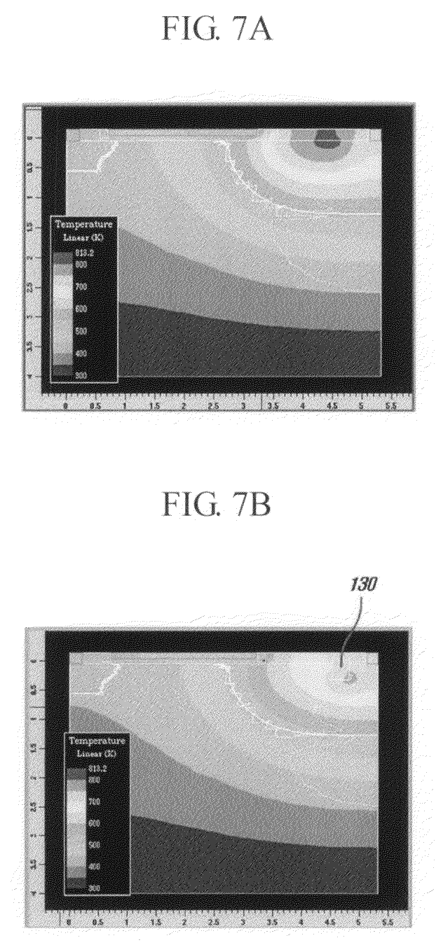

Example FIG. 6A illustrates impact ionization of an ESD protection device without an STI in a drift region when the applied voltage is higher than the breakdown voltage. As illustrated in example FIG. 6A, without an STI in a drift region, impact ionization may be present in a drain active region, which may cause device complications. For example, a device may break due to ESD caused by the relatively high internal temperatures. As illustrated in FIG. 7A, a relatively high temperature distribution is present where a drift region meets a drain active region, in an ESD protection device that does not include a STI in the drift region.

Example FIG. 6B illustrates impact ionization of an ESD protection device that has an STI in a drift region, in accordance with embodiments. In embodiments, STI 130 may be provided in an area where a drift region meets a drain active region. As illustrated in example FIG. 6B, impact ionization is minimized in the proximity of STI 130, in accordance with embodiments. As illustrated in FIGS. 6B and 7B, failure of a semiconductor device under an ESD state due to impact ionization and the temperature distribution may be minimized, in accordance with embodiments. In embodiments, STI 130 may divert current flow (e.g. a relatively high level of current) away from a surface of a semiconductor substrate and deeper into the semiconductor substrate. Diverting of current may improve ESD protection characteristics in a semiconductor device, in accordance with embodiments.

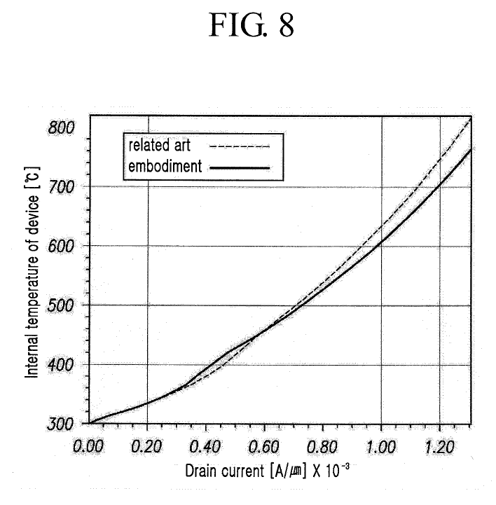

Example FIG. 8 illustrates that an ESD protection structure (e.g. a DENMOS structure) with an STI in a drift area (“embodiment”) may have relatively low internal temperature from ESD current compared to an ESD protection structure without an STI in a drift area (“related art”), in accordance with embodiments. If a high voltage ESD protection device with at least one STI is formed between a drain active region and a drift region, the additional mask process may not be necessary, which may minimize manufacturing costs, in accordance with embodiments. In embodiments, an STI formed between a drain active region and a drift region may divert the direction of operating current away from the surface of the semiconductor device and vertically into the semiconductor substrate, which may minimize damage to a semiconductor device during operation.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate;
a gate formed over the semiconductor substrate;
a drift region formed in the semiconductor substrate, wherein the drift region is adjacent to the gate; and
at least one isolation region formed in the drift region.

2. The apparatus of claim 1, wherein said at least one isolation region is a shallow trench isolation.

3. The apparatus of claim 1, wherein said at least one isolation region comprises two isolation regions.

4. The apparatus of claim 1, wherein said at least one isolation region comprises a single isolation region.

5. The apparatus of claim 1, wherein the drift region is formed in a well region of a transistor.

6. The apparatus of claim 5, wherein:
the well region is implanted with N-type dopants; and
the drift region is implanted with P-type dopants.

7. The apparatus of claim 5, wherein:
the well region is implanted with P-type dopants; and
the drift region is implanted with N-type dopants.

8. The apparatus of claim 1, wherein the gate overlaps one side of the drift region.

9. The apparatus of claim 1, wherein the apparatus is a Drain Extended NMOS transistor.

10. The apparatus of claim 1, wherein said at least one isolation region formed in the drift region is configured to divert current away from the surface of the semiconductor substrate.

11. A method comprising:
forming at least one isolation region in a semiconductor substrate;
forming a drift region in the semiconductor substrate, wherein the drift region surrounds said at least one isolation region; and
forming a gate over the semiconductor substrate.

12. The method of claim 11, wherein said at least one isolation region is a shallow trench isolation.

13. The method of claim 11, wherein said at least one isolation region comprises two isolation regions.

14. The method of claim 11, wherein said at least one isolation region comprises a single isolation region.

15. The method of claim 11, comprising forming a well region in the semiconductor substrate, wherein the drift region is formed in a well region after said forming the well region.

16. The method of claim 15, wherein:
the well region is implanted with N-type dopants; and
the drift region is implanted with P-type dopants.

17. The method of claim 15, wherein:
the well region is implanted with P-type dopants; and
the drift region is implanted with N-type dopants.

18. The method of claim 11, wherein the gate overlaps one side of the drift region.

19. The method of claim 11, wherein the method forms at least a part of a Drain Extended NMOS transistor.

20. The method of claim 11, wherein said at least one isolation region formed in the drift region is configured to divert current away from the surface of the semiconductor substrate.
